(19) United States
(12) Patent Application Publication
(10) Pub. No.: US 2025/0048618 A1
(43) Pub. Date: Feb. 6, 2025

(54) MICROELECTRONIC DEVICES, AND RELATED METHODS, MEMORY DEVICES, AND ELECTRONIC SYSTEMS

(71) Applicant: Micron Technology, Inc., Boise, ID (US)

(72) Inventors: Mitsunari Sukekawa, Hiroshima (JP); Hiroaki Taketani, Sagamihara (JP)

(21) Appl. No.: 18/755,198

(22) Filed: Jun. 26, 2024

Related U.S. Application Data
(60) Provisional application No. 63/516,812, filed on Jul. 31, 2023.

(51) Int. Cl. H10B 12/00

(52) U.S. Cl. CPC H10B 12/33; H10B 12/036; H10B 12/05

(57) ABSTRACT

A microelectronic device includes a vertical access device including a semiconductor pillar and a gate electrode. The semiconductor pillar includes a first portion and second portion vertically adjacent the first portion. The first portion has a first width in a first direction, and includes a source/drain region and a portion of a channel region vertically adjacent the source/drain region. The second portion has a second width in the first direction larger than the first width, and includes an additional portion of the channel region and an additional source/drain region vertically adjacent the additional portion of the channel region. The gate electrode neighbors a sidewall of the semiconductor pillar in a second direction orthogonal to the first direction. The gate electrode vertically overlaps each of the first portion and the second portion of the semiconductor pillar. Methods of forming a microelectronic device, memory devices, and electronic systems are also described.

### CROSS-REFERENCE TO RELATED APPLICATION

This application claims the benefit under 35 U.S.C. § 119 (e) of U.S. Provisional Patent Application Ser. No. 63/516,812, filed Jul. 31, 2023, the disclosure of which is hereby incorporated herein in its entirety by this reference.

### TECHNICAL FIELD

The disclosure, in various embodiments, relates generally to the field of microelectronic device design and fabrication. More specifically, the disclosure relates to methods of forming microelectronic devices, and to related microelectronic devices, memory devices, and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

A relatively common microelectronic device is a memory device. Memory devices are generally provided as internal integrated circuits in computers or other electronic devices. There are many types of memory including, but not limited to, random-access memory (RAM), read only memory (ROM), dynamic random access memory (DRAM), high-resistive random access memory (HRAM), ferroelectric random access memory (FeRAM), synchronous dynamic random access memory (SDRAM), flash memory, and resistance variable memory. Non-limiting examples of resistance variable memory include resistive random access memory (RRAM), conductive bridge random access memory (conductive bridge RAM), magnetic random access memory (MRAM), phase change material (PCM) memory, phase change random access memory (PCRAM), spin-torque-transfer random access memory (STTRAM), oxygen vacancy-based memory, and programmable conductor memory.

Field-effect transistors (FETs) have been utilized as access devices for memory cells of memory devices (e.g., DRAM devices, HRAM devices, FeRAM devices, SDRAM devices, MRAM devices), such as for 4F² memory cells (i.e., where “F” represents minimum lithographic feature width) of memory devices. However, difficulties are frequently encountered in producing the vast arrays of FETs desired for memory device applications while maintaining suitable performance characteristics of the memory devices, such as leakage to adjacent access transistors, resulting in data corruption.

### BRIEF DESCRIPTION OF THE DRAWINGS

FIGS. 1 through 12 are simplified, perspective views of a microelectronic device structure at different processing stages of a method of forming a microelectronic device, in accordance with embodiments of the disclosure.

FIGS. 13 through 24 are simplified, perspective views of a microelectronic device structure at different processing stages of a method of forming a microelectronic device, in accordance with additional embodiments of the disclosure.

FIG. 25 schematically illustrates a region of an example memory array, and a region of peripheral circuitry adjacent to the memory array, in accordance with additional embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional non-volatile memory; conventional volatile memory), but also includes an application specific integrated circuit (ASIC) (e.g., a system on a chip (SoC)), a microelectronic device combining logic and memory, and a graphics processing unit (GPU) incorporating memory.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the drawings, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, the term “intersecting directions,” when referring to the directions of structures, means and includes the structures each defining a length (e.g., longest horizontal dimension) along a direction, such that the direction of at least one of the structures would intersect (e.g., not be wholly parallel to) the direction of at least another of the structures if such directions were drawn in the same plane. For example, “intersecting directions” include, but are not limited to, perpendicular directions, with at least one structure directed along an x-axis and at least one other structure directed along a y-axis, though the structures may be in different levels within a device structure.

As used herein, the term “colinear directions,” when referring to the directions of structures, means and includes the structures each defining a length (e.g., longest horizontal dimension) along a direction, such that the direction of each of the structures would wholly overlap (e.g., not divert from one another, not intersect one another, and not be wholly parallel to one another) if such directions were drawn in the same plane. For example, “colinear directions” include, but are not limited to, one structure, in one level of a device structure, directed along an x-axis and at least one other structure, in at least one other level of the device structure, also directed along the x-axis.

As used herein, features (e.g., structures, materials, regions, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one of the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, other spatially relative terms, such as “below,” “lower,” “bottom,” “above,” “upper,” “top,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation as depicted in the figures. For example, if materials in the figures are inverted, elements described as “below” or “under” or “on bottom of” other elements or features would then be oriented “above” or “on top of” the other elements or features. Thus, the term “below” may encompass both an orientation of above and below, depending on the context in which the term is used, which will be evident to one of ordinary skill in the art. The materials may be otherwise oriented (rotated ninety degrees, inverted, etc.) and the spatially relative descriptors used herein interpreted accordingly.

As used herein, the terms “level” and “elevation” are spatially relative terms used to describe one element's or feature's relationship to another element(s) or feature(s) as illustrated in the figures, using—as a reference point—the primary surface of the substrate on which the reference material or structure is located. As used herein, a “level” and an “elevation” are each defined by a horizontal plane parallel to the primary surface. “Lower levels” and “lower elevations” are nearer to the primary surface of the substrate, while “higher levels” and “higher elevations” are further from the primary surface. Unless otherwise specified, these spatially relative terms are intended to encompass different orientations of the materials in addition to the orientation as depicted in the figures. For example, the materials in the figures may be inverted, rotated, etc., with the spatially relative “elevation” descriptors remaining constant because the referenced primary surface would likewise be respectively reoriented as well.

As used herein, the terms “about” and “approximately,” when either is used in reference to a numerical value for a particular parameter, are inclusive of the numerical value and a degree of variance from the numerical value that one of ordinary skill in the art would understand is within acceptable tolerances for the particular parameter. For example, “about” or “approximately,” in reference to a numerical value, may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the term “substantially,” when referring to a parameter, property, or condition, means and includes the parameter, property, or condition being equal to or within a degree of variance from a given value such that one of ordinary skill in the art would understand such given value to be acceptably met, such as within acceptable manufacturing tolerances. By way of example, depending on the particular parameter, property, or condition that is substantially met, the parameter, property, or condition may be “substantially” a given value when the value is at least 90.0 percent met, at least 95.0 percent met, at least 99.0 percent met, or even at least 99.9 percent met.

As used herein, “and/or” includes any and all combinations of one or more of the associated listed items.

As used herein, the singular forms “a,” “an,” and “the” are intended to include the plural forms as well, unless the context clearly indicates otherwise.

As used herein, the terms “configured” and “configuration” mean and refer to a size, shape, material composition, orientation, and arrangement of a referenced material, structure, assembly, or apparatus so as to facilitate a referenced operation or property of the referenced material, structure, assembly, or apparatus in a predetermined way.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively doped polysilicon, conductively doped germanium (Ge), conductively doped silicon germanium (SiGe)). In addition, a “conductive line structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric oxycarbide material (e.g., silicon oxycarbide (SiOₓC_{y})), at least one hydrogenated dielectric oxycarbide material (e.g., hydrogenated silicon oxycarbide (SiCₓO_{y}H_{z})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10-8 Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., AlₓGa₁₋ₓAs), and quaternary compound semiconductor materials (e.g., GaₓIn₁₋ₓAs_{y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

As used herein, the term “sacrificial material” means and includes a material that is formed and/or employed during a fabrication process but which is subsequently removed, in whole or in part, prior to completion of the fabrication process. A “partially-sacrificial” material means and includes a sacrificial material from which only one or more portions is or are removed prior to completion of the fabrication process. A “wholly-sacrificial” material means and includes a sacrificial material that is substantially entirely removed prior to completion of the fabrication process.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

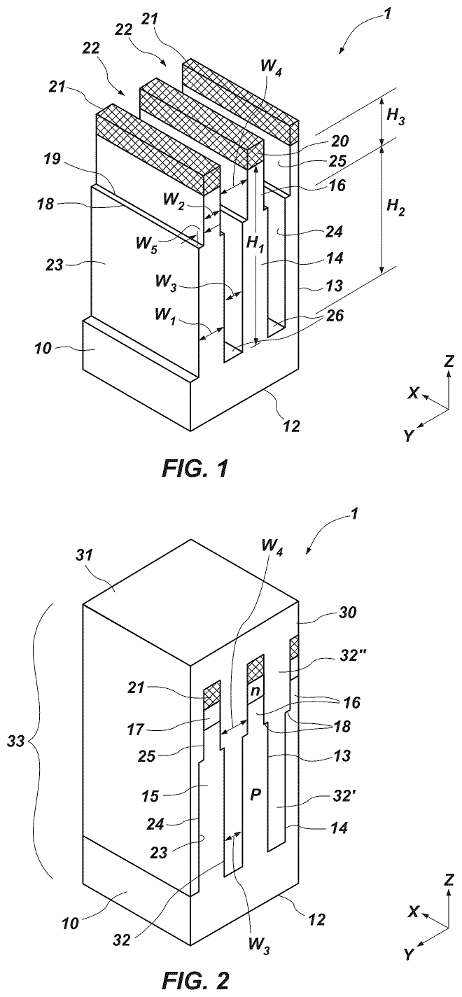

FIGS. 1 through 11 are simplified, perspective views of a microelectronic device structure (e.g., a memory device structure, such as a DRAM structure) at different processing stages of a method of forming a microelectronic device (e.g., a memory device, such as a DRAM device, an HRAM device, an FeRAM device, an SDRAM device, an MRAM device), in accordance with embodiments of the disclosure. With the description provided below, it will be readily apparent to one of ordinary skill in the art that the methods described herein may be used to form various microelectronic devices, such as to form microelectronic devices where three-dimensional (3D) scaling is advantageous.

Referring to FIG. 1, a microelectronic device structure 1 is formed to include a first semiconductor structure 10 including a semiconductor base 12 and semiconductor projections 13 (e.g., semiconductor pillars) vertically extending (e.g., in the Z-direction) from and integral (e.g., unitary) with the semiconductor base 12; and conductive line structures 21 (e.g., bit line structures, data line structures, digit line structures) on or over semiconductor projections 13. In some embodiments, the first semiconductor structure 10 is formed of and includes at least one semiconductive material, such as silicon (e.g., monocrystalline silicon, polycrystalline silicon). In addition, the microelectronic device structure 1 further includes trenches 22 vertically extending into the first semiconductor structure 10 in the Z-direction, horizontally extending in parallel in the X-direction, and horizontally interposed between neighboring semiconductor projections 13 and the neighboring conductive line structures 21 in the Y-direction. The trenches 22 are also referred to herein as x-axis trenches 22.

The x-axis trenches 22 may be formed to vertically terminate at a desirable vertical depth within the first semiconductor structure 10; such as, for example, a vertical depth within a range of from about 150 nanometers (nm) to about 300 nm (e.g., about 180 nm) from an uppermost surface of the first semiconductor structure 10. The semiconductor projections 13 may horizontally alternate in the Y-direction with x-axis trenches 22, and may individually have a first height H₁ within a range of from about 150 nm to about 300 nm (e.g., about 180 nm). The x-axis trenches 22 have horizontal boundaries partially defined by sidewalls 23 of the adjacent semiconductor projections 13 and lower boundaries defined by upper surfaces 26 of the semiconductor base 12 of the first semiconductor structure 10. In some embodiments, the sidewalls 23 of the semiconductor projections 13 defining the x-axis trenches 22 include first sections 24 (e.g., lower sections) proximate the semiconductor base 12, and second sections 25 (e.g., upper sections) vertically adjacent to the first sections 24 and horizontally offset from the first sections 24 in a second direction represented by the y-axis (also referred to herein as the “Y-direction”).

Each semiconductor projection 13 includes a first portion 14 proximate the semiconductor base 12, and a second portion 16 vertically overlying the first portion 14 and having a smaller horizontal cross-sectional area than the first portion 14. The first portion 14 of an individual semiconductor projection 13 has a first width W₁ which is at least partially defined by the horizontal distance between first sections 24 of the sidewalls 23 of the semiconductor projection 13. Similarly, the second portion 16 of an individual semiconductor projection 13 has a second width W₂ which is at least partially defined by the horizontal distance between second sections 25 of the sidewalls 23 of the semiconductor projection 13. The first width W₁ of the first portion 14 of an individual semiconductor projection 13 is greater than the second width W₂ of the second portion 16 of the semiconductor projection 13. Complementary therewith, a third width W₃ between first sections 24 of neighboring sidewalls 23 of neighboring semiconductor projections 13 is less than a fourth width W₄ between second sections 25 of neighboring sidewalls 23 of neighboring semiconductor projections 13.

The first width W₁ of the first portions 14 of the semiconductor projections 13 may be greater than or equal to about 20 nm (e.g., within a range of from about 15 nm to about 30 nm). The second width W₂ of the second portions 16 of the semiconductor projections 13 may be less than about 10 nm (e.g., within a range of from about 5 nm to about 9 nm).

Ledges 18 are formed along upper edges of the first portions 14 of the semiconductor projections 13. The ledges 18 have ledge surfaces 19 which extend along the upper edges on each side of the first portions 14 of the semiconductor projections 13. The second portions 16 of the semiconductor projections 13 may be positioned equidistant between the oppositely disposed ledges 18. The ledge surfaces 19 of the ledges 18 may have a fifth width W₅ which is less than or equal to about 10 nm (e.g., within a range of from about 5 nm to about 10 nm).

The first height H₁ of the semiconductor projections 13 is at least partially defined by the vertical distance between the upper surfaces 26 of the semiconductor base 12 of the first semiconductor structure 10 and uppermost boundaries (e.g., upper surfaces, top surfaces) of the second portions 16 of the semiconductor projections 13. The first portions 14 of the semiconductor projections 13 have a second height H₂, which extends vertically from the upper surfaces 26 of the semiconductor base 12 of the first semiconductor structure 10 to the ledge surfaces 19 of the ledges 18. The second portions 16 of the semiconductor projections 13 have a third height H₃ which extends vertically from the ledge surfaces 19 to the uppermost boundaries (e.g., upper surfaces, top surfaces) of the second portions 16. The first height H₁ of the semiconductor projections 13 is equal to the second height H₂ of the first portions 14 plus the third height H₃ of the second portions 16. The second height H₂ of the first portions 14 may be greater than the third height H₃ of the second portions 16. For example, the third height H₃ of the second portions 16 may be less than or equal to about 60 percent (%) of the second height H₂ of the first portions 14 of the semiconductor projections 13, such as less than or equal to about 40% of the second height H₂ of the first portions 14, or less than or equal to about 20% of the second height H₂ of the first portions 14.

In some embodiments, the x-axis trenches 22 are formed in at least two stages. A first stage includes forming initial trenches individually having the third width W₃, and individually vertically extending through the first semiconductor structure 10 to vertical elevations of the upper surfaces 26 of the semiconductor base 12. A second stage includes horizontally trimming back upper sections of the resulting initial semiconductor projections to form the x-axis trenches 22 and the semiconductor projections 13. Upper sections of the x-axis trenches 22 have the fourth width W₄ and may vertically extend to vertical elevations of the ledge surfaces 19 of the ledges 18 of the resulting semiconductor projections 13. Lower sections of the x-axis trenches 22 have the third width W₃ and vertically extend from the ledge surfaces 19 of the ledges 18 to the upper surfaces 26 of the semiconductor base 12 of the first semiconductor structure 10.

Still referring to FIG. 1, the first conductive line structures 21 are formed vertically on or over the second portions 16 of each of the semiconductor projections 13. The first conductive line structures 21 may be formed of and include a first conductive material 20. The first conductive material 20 may comprise one or more conductive materials. In some embodiments, the first conductive material 20 includes tungsten, either alone or in combination with one or more conductive barrier materials (e.g., oxidation-resistant materials which protect the tungsten from oxidation in embodiments in which the tungsten may be exposed to oxygen).

The first conductive line structures 21 may be formed to any suitable dimensions (e.g., width, thickness). By way of example, the first conductive line structures 21 may individually be formed to a width, in the Y-direction, equal to about the second width W₂ of the second portion 16 of an individual semiconductor projection 13 (e.g., less than about 10 nm). In some embodiments, the first conductive line structures 21 are formed to a width within a range of from about 5 nm to about 9 nm. The first conductive line structures 21 may be formed to any suitable pitch. The first conductive line structures 21 may be spaced apart from one another by a distance equal to about the fourth width W₄ between the second sections 25 of the sidewalls 23 of the semiconductor projections 13 horizontally neighboring one another in the Y-direction.

The first semiconductor structure 10 (including the semiconductor base 12 and the semiconductor projections 13), and the first conductive line structures 21 may be formed using any suitable processing. For instance, the first conductive material 20 may be formed on or over a semiconductor material; and then a first material removal process (e.g., a first process including photolithographic patterning and etching) may be effectuated to form preliminary trenches etched through the first conductive material 20 and into the semiconductor material. Thereafter, a second material removal process (e.g., a second process including additional photolithographic patterning and etching) may be effectuated to horizontally expand, in the Y-direction, upper portions of the preliminary trenches to form the first conductive line structures 21, the first semiconductor structure 10 including the semiconductor base 12 and the semiconductor projections 13 (including the first portions 14, the second portions 16, and the ledges 18 thereof), and the x-axis trenches 22.

Referring next to FIG. 2, a first insulative material 30 is formed (e.g., non-conformally deposited) to fill the x-axis trenches 22 (FIG. 1) and to overlie the first conductive line structures 21 of the microelectronic device structure 1. A lower boundary of the first insulative material 30 may be non-planar, and an upper boundary of the first insulative material 30 may be substantially planar. In at least some embodiments, the first insulative material 30 comprises a dielectric oxide material, such as silicon dioxide.

The first insulative material 30 forms insulative structures 32 interposed between semiconductor projections 13 horizontally neighboring one another in the Y-direction. In some embodiments, the insulative structures 32 individually include a first section 32′ and a second section 32″. The first section 32′ of an individual insulative structure 32 may vertically overlap and horizontally extend between the first portions 14 of semiconductor projections 13 horizontally neighboring one another in the Y-direction. The first sections 32′ may individually exhibit the third width W₃ in the Y-direction. The second sections 32″ of an individual insulative structure 32 may vertically overlap and horizontally extend between the second portions 16 of semiconductor projections 13 horizontally neighboring one another in the Y-direction. The second sections 32″ may individually exhibit the fourth width W₄ in the Y-direction. Operational characteristics of devices constructed in accordance with embodiments of the disclosure may be adjusted, as desired, in part by modifying the fourth width W₄ of the second sections 32″ of the insulative structures 32 (e.g., modifying the fourth width W₄ of the x-axis trenches 22 between neighboring semiconductor projections 13) in combination with dopant concentrations of various doped regions, and described in further detail below.

The semiconductor projections 13 and the insulative structures 32 may horizontally extend in parallel in the X-direction. In addition, the semiconductor projections 13 and the insulative structures 32 may horizontally alternate with one another in the Y-direction perpendicular to the X-direction.

In some embodiments, the first section 32′ and the second section 32″ of individual insulative structures 32 are integral (e.g., unitary) and continuous with one another. The first section 32′ and the second section 32″ are each formed of and include the first insulative material 30 (e.g., silicon dioxide). In some embodiments, the first section 32′ and the second section 32″ of each insulative structure 32 each comprise silicon dioxide, however, the first section 32′ and the second section 32″ may have different densities than one another (e.g., the density of the second section 32″ may be greater than the density of the first section 32′).

In some embodiments, at least a portion of the first insulative material 30 is considered to be a dielectric bonding material. The first insulative material 30 may have an upper surface 31 that is substantially planar. The upper surface 31 may be formed using a suitable planarization process, such as CMP.

With continued reference to FIG. 2, the semiconductor projections 13 may be formed to individually include a first doped region 15 (e.g., a channel region) and a second doped region 17 (e.g., a drain region). One of the first doped region 15 and the second doped region 17 may be n-type doped while the other of the first doped region 15 and the second doped region 17 may be p-type doped. In some embodiments, the first doped region 15 is p-type doped, such as p-type doped to concentration in a range of from about −10¹³ cm⁻³ to about −10¹⁸ cm⁻³, and the second doped region 17 is n-type doped, such n-type doped as to concentration in a range of from about 10¹⁵ cm⁻³ to about 10²⁰ cm⁻³. In additional embodiments, the first doped region 15 is p-type doped to the point of saturation (e.g., greater than or equal to about −10¹⁸ cm⁻³). The doping of first doped region 15 and the second doped region 17 may be reversed so that the second doped region 17 is p-type doped and the first doped region 15 is n-type doped. In additional embodiments, the first doped region 15 does not include p-type dopant or n-type dopant (e.g., the first doped region 15 may, instead, be considered an undoped region). The first doped regions 15, in some embodiments, are disposed in part within the vertical boundaries of the first portions 14 of the semiconductor projections 13 and extend upwardly past the ledges 18 thereof into and between the vertical boundaries of the second portions 16 of the semiconductor projections 13. In some embodiments, the second doped regions 17 are disposed entirely within vertical boundaries of the second portions 16 of the semiconductor projections 13. The second doped regions 17 may extend a distance downward from the upper boundaries of the second portions 16 of the semiconductor projections 13 (e.g., to a vertical depth within a range of from about 10 nm to about 50 nm from upper boundaries of the second portions 16, such as from about 20 nm to about 30 nm). The doping may be accomplished utilizing any suitable processing, such as by implanting dopant (e.g., at least one n-type dopant or at least one p-type dopant) into the first semiconductor structure 10. Although the first doped regions 15 and the second doped regions 17 are first shown at the process stage of FIG. 2, the first doped regions 15 and the second doped regions 17 may be formed at an earlier process stage, such as the process stage previously described with reference to FIG. 1.

The semiconductor base 12, the semiconductor projections 13, the first conductive line structures 21, and the insulative structures 32 may be considered together to form a first assembly 33.

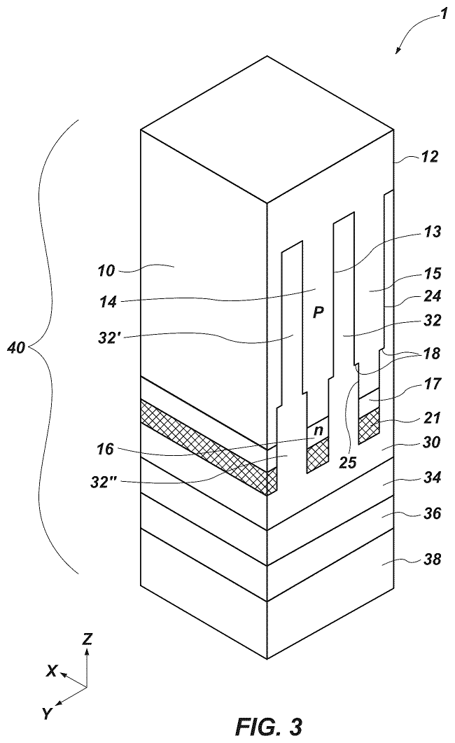

Referring to FIG. 3, the first assembly 33 of microelectronic device structure 1 may be inverted and attached (e.g., bonded) to a construction including a second semiconductor structure 34. In some embodiments, the first insulative material 30 is bonded to the second semiconductor structure 34. A material composition of the second semiconductor structure 34 may be substantially the same as or may be different than a material composition of the first semiconductor structure 10. In some embodiments, the second semiconductor structure 34 is formed of and includes at least one semiconductive nitride material, such as one or more of gallium nitride, aluminum nitride, and indium nitride.

As shown in FIG. 3, the second semiconductor structure 34 may be formed on or over a first dielectric material 36. In some embodiments, the first dielectric material 36 comprises insulative material, such as one or more of dielectric oxide material (e.g., silicon dioxide) and dielectric nitride material (e.g., silicon nitride). In addition, as also shown in FIG. 3, the first dielectric material 36 may be formed on or over a substrate 38. In some embodiments, the substrate 38 is formed of and includes semiconductive material (e.g., silicon). For example, the substrate 38 may comprise a semiconductive wafer, such as a silicon wafer. The combination of the first assembly 33 (FIG. 2), the second semiconductor structure 34, the first dielectric material 36, and the substrate 38 may form a second assembly 40.

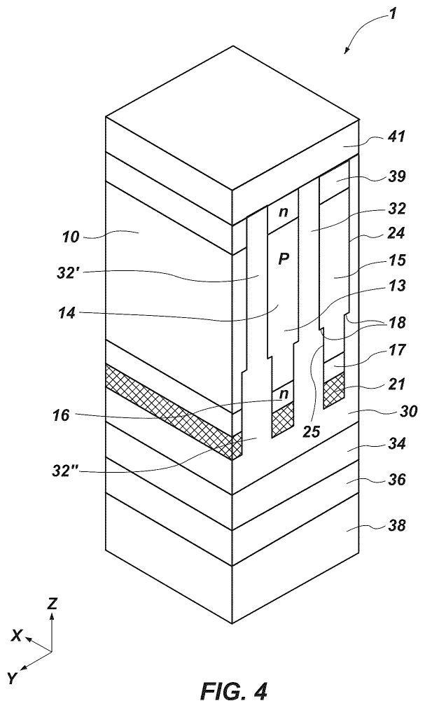

Referring to FIG. 4, a portion (e.g., at least the semiconductor base 12 (FIG. 3)) of the first semiconductor structure 10 is removed such that the upper ends of the first portions 14 of the semiconductor projections 13 are substantially coplanar with the upper ends of the first sections 32′ of the insulative structures 32. In addition, a first mask material 41 may be formed over remainders of the first portions 14 of the semiconductor projections 13 and the first sections 32′ of the insulative structures 32. In some embodiments, the first mask material 41 is formed of and includes dielectric material, such as dielectric nitride material (e.g., silicide nitride).

Third doped regions 39 (e.g., source regions) may be formed in upper regions of the first portions 14 of the semiconductor projections 13. The third doped regions 39 may be n-type doped or may be p-type doped. In some embodiments, the third doped regions 39 are individually n-type doped, such as to concentration in a range of from about 10¹⁵ cm⁻³ to about 10²⁰ cm⁻³. Doping may be accomplished utilizing suitable processing, such as implanting of appropriate dopant (e.g., n-type dopant, p-type dopant) into the upper regions of the first portions 14 of the semiconductor projections 13. Such processing may be effectuated prior to the formation of the first mask material 41. As shown, the third doped regions 39 extend downwardly from the upper ends of the first portions 14 of the semiconductor projections 13 (e.g., to a vertical depth within a range of from about 10 nm to about 50 nm from uppermost boundaries of the remainders of the first portions 14, such as from about 20 nm to about 40 nm).

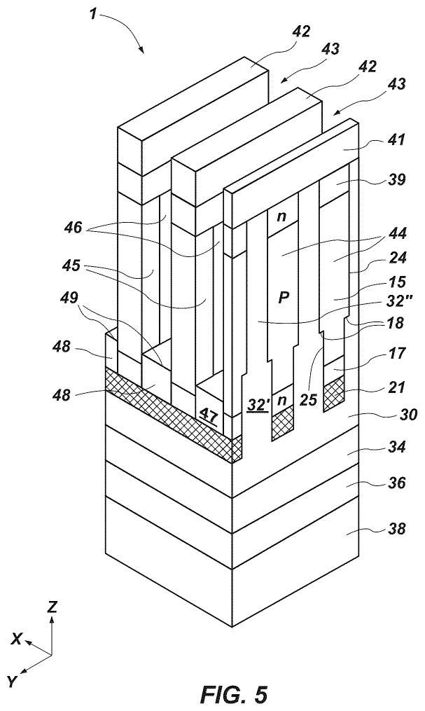

Referring next to FIG. 5, the first mask material 41 is patterned to form patterned masking lines 42 horizontally extending in parallel with one another in the Y-direction. The first mask material 41 may be patterned into the patterned masking lines 42 utilizing any suitable methodology. For instance, in some embodiments, a photoresist material is formed on or over the first mask material 41, is patterned (e.g., photoexposed and developed), and then openings formed in the patterned photoresist material are extended into the first mask material 41 to form the patterned masking lines 42. The patterned masking lines 42 may be removed during subsequent processing stages, or may remain in a final device formed through the methods of the disclosure.

The patterned masking lines 42 may be employed to form additional trenches 43 vertically extending into the first semiconductor structure 10 (FIG. 4) and the first insulative material 30 of the microelectronic device structure 1. The trenches 43 horizontally extend in parallel in the Y-direction, and are also referred to as y-axis trenches 43. The y-axis trenches 43 may have any suitable dimensions. In some embodiments, the y-axis trenches 43 have vertical depths (e.g., vertical heights) within a range of from about 100 nm to about 200 nm (e.g., about 150 nm).

The y-axis trenches 43 vertically extend in the Z-direction downward into and through portions of the semiconductor projections 13 (FIG. 4) and the insulative structures 32 (FIG. 4). The formation of the y-axis trenches 43 effectuates the formation of semiconductor pillars 44 from the semiconductor projections 13. The semiconductor pillars 44 have semiconductor pillar edges 45 (e.g., side surfaces) which are exposed by the y-axis trenches 43. Inner walls 46 of the first insulative material 30 (e.g., of remainders of the insulative structures 32 (FIG. 4)) are disposed between the semiconductor pillar edges 45 and are also exposed by the y-axis trenches 43.

In some embodiments, the y-axis trenches 43 are formed using an etching process (e.g., an anisotropic etching process) that selectively removes exposed portions of the first semiconductor structure 10 (FIG. 4) and the first insulative material 30 relative to the patterned masking lines 42. The exposed portions of the first semiconductor structure 10 and the first insulative material 30 may be removed at substantially the same rate as one another. Accordingly, lower boundaries (e.g., bottoms) of the y-axis trenches 43, as defined by surfaces of the remainder of the first semiconductor structure 10 and the first insulative material 30 may be substantially planar. In some embodiments, the lower boundaries of the y-axis trenches 43 vertically overlie upper surfaces of the first conductive line structures 21 and the first insulative material 30 disposed thereinbetween.

Still referring to FIG. 5, a second dielectric material 47 may be formed and processed (e.g., etched) within the y-axis trenches 43 to form insulative step structures 48 therein. The insulative step structures 48 may individually have an upper surface 49 exposed within a respective y-axis trench 43. In some embodiments, the upper surfaces 49 of the insulative step structures 48 may have a height in the Z-direction that is above the height in the Z-direction of the second doped regions 17 of semiconductor pillars 44. In additional embodiments, the insulative step structures 48 have a height in the Z-direction that is approximately the same as the height in the Z-direction of the second doped regions 17 of semiconductor pillars 44.

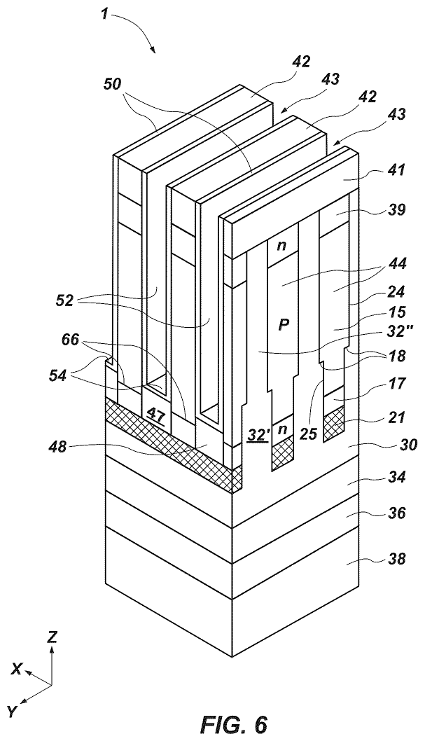

Referring to FIG. 6, dielectric liner material 50 is formed in the y-axis trenches 43 of the microelectronic device structure 1. The dielectric liner material 50 may also be referred to herein as a gate dielectric material 50. The gate dielectric material 50 is formed over and along the semiconductor pillar edges 45 (FIG. 5) of the semiconductor pillars 44 and the inner walls 46 (FIG. 5) of the first insulative material 30 disposed between the semiconductor pillars 44. Within the y-axis trenches 43, the gate dielectric material 50 may include side portions 52 on the semiconductor pillar edges 45 of the semiconductor pillars 44 and the inner walls 46 of the first insulative material 30, and, optionally, bottom portions 54 on or over the upper surfaces 49 of the insulative step structures 48. Within an individual y-axis trench 43, the bottom portion 54 of the gate dielectric material 50 may be integral and continuous with the side portions 52 of the gate dielectric material 50. In some embodiments, upper surfaces of the bottom portions 54 of the gate dielectric material 50 are vertically offset from (e.g., are vertically above) interfaces 66 between the first doped region 15 and second doped region 17 of the individual semiconductor pillars 44.

The gate dielectric material 50 may be formed of and include insulative material. In some embodiments, the gate dielectric material 50 is formed of and includes silicon dioxide. In some embodiments, the gate dielectric material 50 is formed (e.g., conformally deposited) inside and outside of the y-axis trenches 43, and then portions of the gate dielectric material 50 are removed (e.g., by way of CMP) while additional portions of the gate dielectric material 50 within the y-axis trenches 43 are maintained. The side portions 52 and the bottom portions 54 of the gate dielectric material 50 may have a thickness within a range of from about 3 nm to about 7 nm (e.g., about 5 nm).

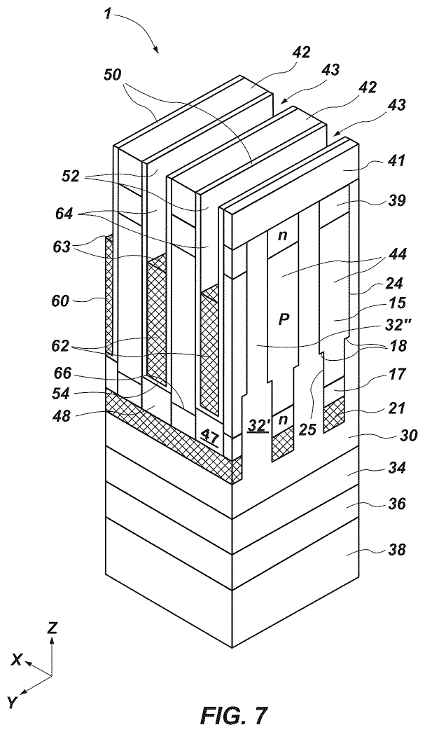

Referring to FIG. 7, a second conductive material 60 is formed within the y-axis trenches 43 and over the gate dielectric material 50. Within individual y-axis trenches 43, the second conductive material 60 may be horizontally interposed in the X-direction between the side portions 52 of the gate dielectric material 50, and may vertically overlie the bottom portion 54 of the gate dielectric material 50. In some embodiments, the second conductive material 60 is formed of and includes titanium nitride.

The second conductive material 60 may be processed (e.g., vertically recessed) to form second conductive line structures 62 (e.g., gate electrodes, access lines, word lines) within the y-axis trenches 43. The second conductive line structures 62 may horizontally extend in parallel in the Y-direction. In some embodiments, the second conductive line structures 62 are employed as gate electrodes. The second conductive line structures 62 may vertically overlap the first doped regions 15 of the semiconductor pillars 44. In some embodiments, the second conductive line structures 62 are substantially confined within vertical boundaries of the first doped regions 15 of the semiconductor pillars 44. In additional embodiments, the second conductive line structures 62 also partially vertically overlap the second doped regions 17 of the semiconductor pillars 44.

Following the formation of the second conductive line structures 62, remaining portions 64 of the y-axis trenches 43 may vertically overlie the second conductive line structures 62. Upper surfaces 63 of the second conductive line structures 62 may define bottoms of the remaining portions 64 of the y-axis trenches 43. In some embodiments, the upper surfaces 63 of the second conductive line structures 62 are vertically offset in the Z-direction from the upper surfaces of the patterned masking lines 42 by a distance within a range of from about 50 nm to about 150 nm, such as from about 75 nm to about 100 nm.

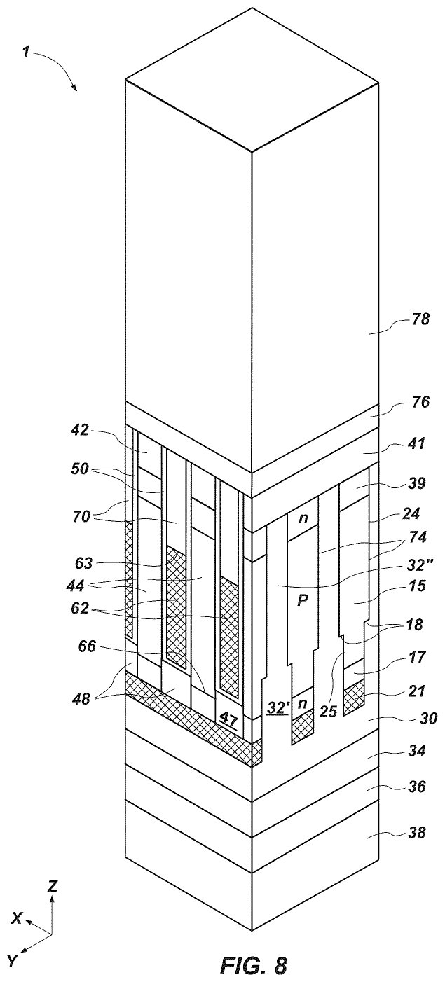

Referring to FIG. 8, a second insulative material 70 may be formed within and may substantially fill the remaining portions 64 (FIG. 7) of the y-axis trenches 43 (FIG. 7). The second insulative material 70 may be formed on or over the upper surfaces 63 of the second conductive line structures 62 within the remaining portions 64 (FIG. 7) of the y-axis trenches 43. The second insulative material 70 may be formed to be substantially confined within the boundaries of the y-axis trenches 43 (FIG. 7) (e.g., using a CMP process following conformal deposition of the second insulative material 70). In some embodiments, the second insulative material 70 is formed of and includes dielectric oxide material (e.g., silicon oxide). In addition, after forming the second insulative material 70, a second mask material 76 may be formed over the patterned masking lines 42, the gate dielectric material 50, and the second insulative material 70, and a sacrificial mask material 78 may be formed over the second mask material 76. The second mask material 76 and the sacrificial mask material 78 may each have etch selectively relative at least to the second insulative material 70 and additional materials of storage node elements to be formed using the second mask material 76 and the sacrificial mask material 78 (as described in further detail below). In some embodiments, the second mask material 76 is formed of and includes a dielectric nitride material (e.g., silicon nitride), and the sacrificial mask material 78 is formed of and includes an oxide material (e.g., silicon dioxide).

Still referring to FIG. 8, the semiconductor pillars 44 may form portions of vertical access devices 74 (e.g., vertical transistors). An individual vertical access device 74 may include a channel region comprising the first doped region 15 of an individual semiconductor pillar 44, a drain region comprising the second doped region 17 of the semiconductor pillar 44, and a source region comprising the third doped region 39 of the semiconductor pillar 44. In addition, the vertical access device 74 may include a gate electrode comprising one of the second conductive line structures 62, and a gate dielectric material comprising the dielectric liner material 50. An individual second conductive line structure 62 may be utilized as a gate electrode for multiple vertical access devices 74. The second conductive line structures 62 may have upper portions disposed above the ledges 18 of the vertical access devices 74 and adjacent the narrower first sections 32′ of neighboring insulative structures 32, and lower portions disposed below the ledges 18 of the vertical access devices 74 and adjacent the wider second sections 32″ of neighboring insulative structures 32. In some embodiments, the bottom portions 54 of the gate dielectric material 50 are also disposed below the ledges 18 of the vertical access devices 74. The additional amount of the first insulative material 30 present in the wider second sections 32″ of the insulative structures 32 disposed below the ledges 18 of neighboring vertical access devices 74 and adjacent lower portions of the second conductive line structures 62 reduces (e.g., minimizes) leakage between adjacent vertical access devices 74, thereby reducing (e.g., minimizing) data corruption. Modifying (e.g., increasing, decreasing) the additional amount of the first insulative material 30 present in the wider second sections 32″ of the insulative structures 32 disposed below the ledges 18 of neighboring vertical access devices 74 and adjacent lower portions of the second conductive line structures 62 permits control over the amount of leakage which occurs between adjacent vertical access devices 74.

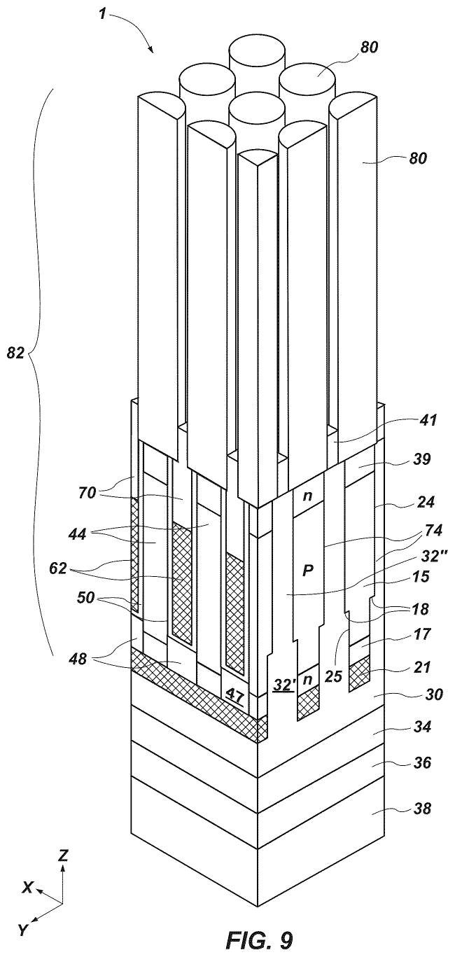

Referring to FIG. 9, openings may be formed to vertically extend through the sacrificial mask material 78 (FIG. 8), the second mask material 76 (FIG. 8), and the first mask material 41 of the patterned masking lines 42 (FIG. 8) and to at least partially expose the semiconductor pillars 44 (FIG. 8) (e.g., to the third doped regions 39 thereof) of the vertical access devices 74. The openings may horizontally overlap and vertically extend to the semiconductor pillars 44 of the vertical access devices 74. Storage node elements 80 (e.g., capacitors) are then formed within the resulting openings, and may be in electrical communication with the vertical access devices 74. The combination of an individual storage node element 80 and an individual vertical access device 74 forms a memory cell 82. As shown in FIG. 9, following the formation of the storage node elements 80, remaining portions of the sacrificial mask material 78 and the second mask material 76 may be substantially removed while maintaining the storage node elements 80. Remaining portions of the first mask material 41 may also be removed (e.g., substantially removed), or may be at least partially maintained, as shown in FIG. 9.

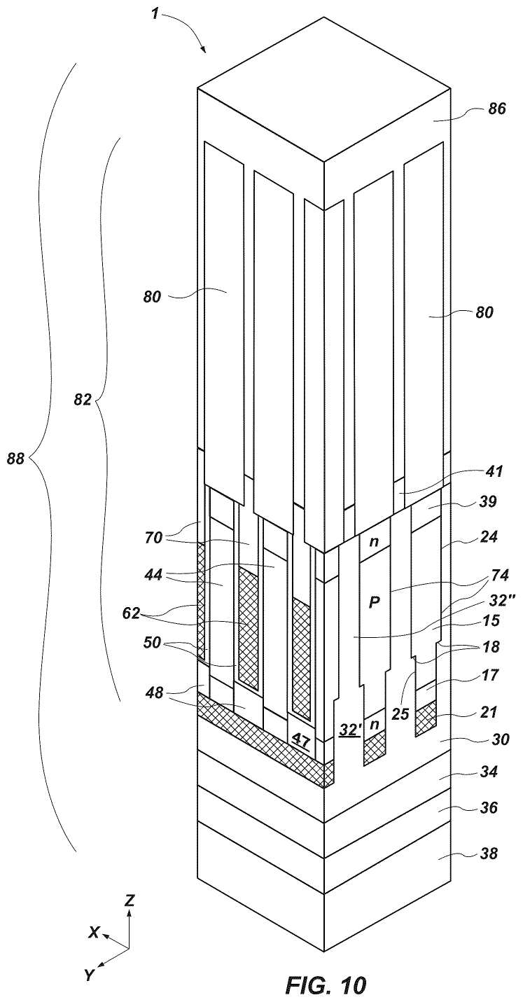

Referring to FIG. 10, following the removal of the remaining portions of the sacrificial mask material 78 (FIG. 8) and the second mask material 76 (FIG. 8) (and, optionally, the first mask material 41), a third dielectric material 86 may be formed within the resulting void spaces between the storage node elements 80. As shown in FIG. 10, the third dielectric material 86 may substantially cover and surround the storage node elements 80. Upper electrodes (not shown) of the storage node elements 80 may be operatively positioned (e.g., embedded) within the third dielectric material 86. A material composition of the third dielectric material 86 may be substantially the same as or may be different than that of the second insulative material 70. In some embodiments, the third dielectric material 86 is formed of and includes silicon oxide. In additional embodiments, the third dielectric material 86 is formed of and includes a high-k dielectric material, such as hafnium dioxide. A third assembly 88 may result after the formation of the third dielectric material 86, as shown in FIG. 10.

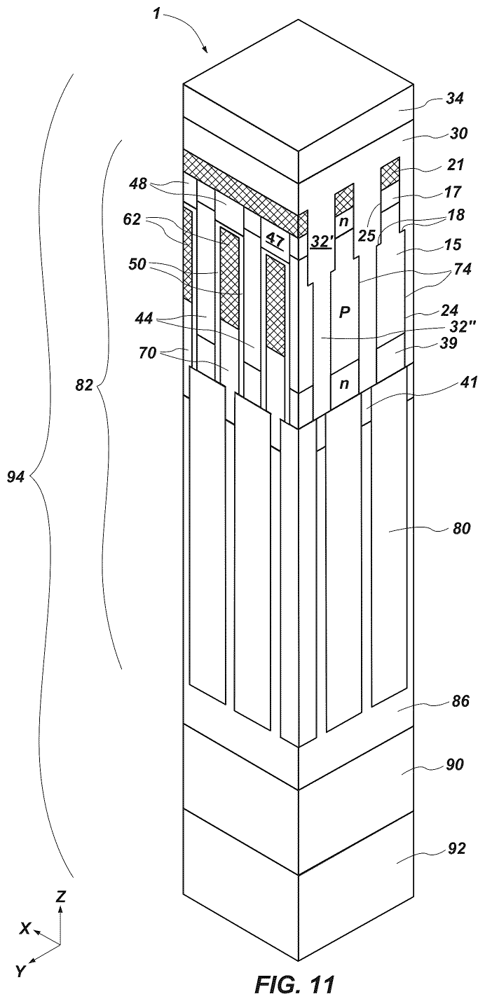

Referring to FIG. 11, an additional substrate 92 (e.g., an additional wafer, such as additional silicon wafer) may be attached (e.g., bonded) to the third assembly 88 (FIG. 10), and then the resulting structure may be vertically inverted. In some embodiments, the additional substrate 92 is attached to the third assembly 88 by way of a third insulative material 90 (e.g., dielectric oxide material). For example, a separate assembly including the additional substrate 92 and the third insulative material 90 may be attached to the third assembly 88 by bonding the third insulative material 90 to the third dielectric material 86 of the third assembly 88. In addition, following inversion, the substrate 38 (FIG. 10) and the first dielectric material 36 (FIG. 10) may be removed while at least partially maintaining the second semiconductor structure 34. As shown in FIG. 11, a fourth assembly 94 may result from such process acts.

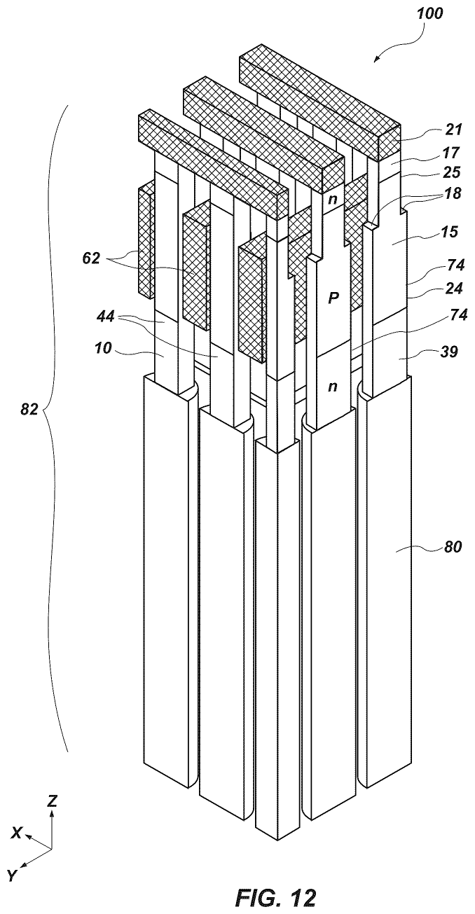

Referring to FIG. 12, a microelectronic device 100 formed through the process described with reference to FIGS. 1 through 11 is depicted. The microelectronic device 100 may have a 4F² cell architecture, and may include the fourth assembly 94 (FIG. 11). However, in FIG. 12 some features (e.g., material, structures) of the fourth assembly 94 are omitted for clarity and case of understanding the drawing and related description. As shown in FIG. 12, the microelectronic device 100 may include an array of 4F² memory cells 82, wherein each memory cell 82 includes one of the vertical access devices 74 and one of the storage node elements 80 previously described herein.

An advantage of the processing of FIGS. 1-11 is that the additional amount of the first insulative material 30 in the wider second sections 32″ of the insulative structures 32 below the ledges 18 of neighboring vertical access devices 74 (e.g., vertical transistors) and adjacent lower portions of the second conductive line structures 62 (e.g., wordlines) reduces (e.g., minimizes) leakage between adjacent vertical access devices 74, thereby reducing (e.g., minimizing) data corruption, allowing for higher levels of integration of vertical transistors in 4F² cell architectures.

Thus, in accordance with embodiments of the disclosure, a microelectronic device includes a vertical access device including a semiconductor pillar and a gate electrode. The semiconductor pillar includes a first portion and second portion vertically adjacent the first portion. The first portion has a first width in a first horizontal direction and includes a source/drain region, and a portion of a channel region vertically adjacent the source/drain region. The second portion has a second width in the first horizontal direction larger than the first width and includes an additional portion of the channel region, and an additional source/drain region vertically adjacent the additional portion of the channel region. The gate electrode neighbors a sidewall of the semiconductor pillar in a second horizontal direction orthogonal to the first horizontal direction. The gate electrode vertically overlaps each of the first portion and the second portion of the semiconductor pillar.

Furthermore, in accordance with embodiments of the disclosure, a method of forming a microelectronic device includes forming a preliminary structure including semiconductive projections, conductive line structures, and dielectric material. The semiconductive projections vertically extend from a semiconductive base and horizontally extend in a first direction. The semiconductive projections each include a first portion having a first horizontal width in a second direction orthogonal to the first direction, and a second portion having a second horizontal width in the second direction, the second horizontal width smaller than the first horizontal width. The conductive line structures are on the semiconductive projections. The dielectric material is horizontally interposed between the semiconductive projections and the conductive line structures in the second direction. Trenches are formed to vertically extend through the semiconductive projections and the dielectric material and to respectively horizontally extend in the first direction. The trenches form semiconductor pillars from the semiconductive projections. The trenches are partially filled with gate dielectric material. Gate electrodes are formed within the trenches and on the gate dielectric material. Remaining portions of the trenches are filled with additional dielectric material after forming the gate electrodes.

Moreover, in accordance with embodiments of the disclosure, a memory device includes memory devices and conductive line structures vertically neighboring and in electrical communication with the memory devices. The memory devices each include a vertical access device and a storage node device. The vertical access device includes a semiconductor pillar and a gate electrode. The semiconductor pillar includes a first portion and a second portion vertically adjacent the first portion. The first portion has a first width in a first horizontal direction and includes a source/drain region, and a portion of a channel region vertically adjacent the source/drain region. The second portion has a second width in the first horizontal direction larger than the first width. The second portion includes an additional portion of the channel region, and an additional source/drain region vertically adjacent the additional portion of the channel region. The gate electrode neighbors a sidewall of the semiconductor pillar in a second horizontal direction orthogonal to the first horizontal direction. The gate electrode vertically overlaps each of the first portion and the second portion of the semiconductor pillar. The storage node device vertically neighbors and is in electrical communication with the additional source/drain region of the vertical access device. The conductive line structures are relatively more vertically proximate to the vertical access device of each of the memory devices than the storage node device of each of the memory devices.

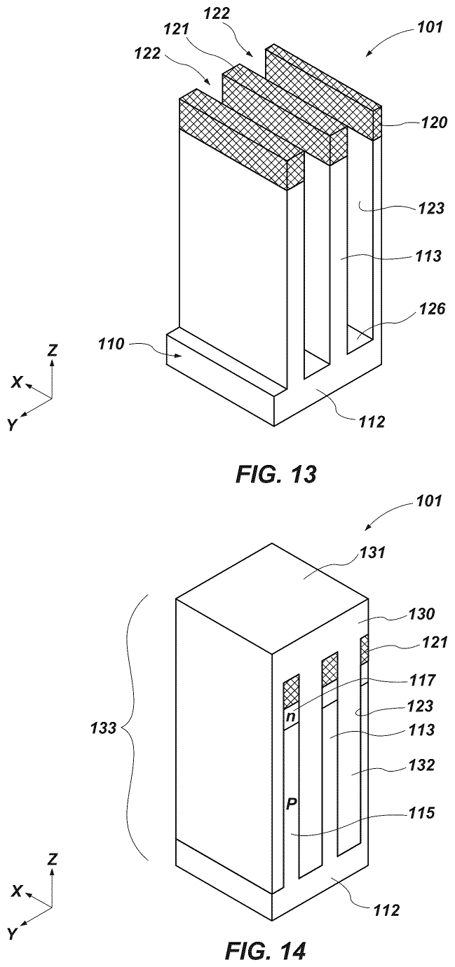

FIGS. 1-12 may be considered to describe a first exemplary method of forming vertical transistors into 4F² cell architectures. Another exemplary method is described below with reference to FIGS. 13-24.

FIGS. 13 through 24 are simplified, perspective views of a microelectronic device structure (e.g., a memory device structure, such as a DRAM structure) at different processing stages of another method of forming a microelectronic device (e.g., a memory device, such as a DRAM device, an HRAM device, an FeRAM device, an SDRAM device, an MRAM device), in accordance with embodiments of the disclosure. With the description provided below, it will be readily apparent to one of ordinary skill in the art that the methods described herein may be used to form various microelectronic devices, such as to form microelectronic devices where three-dimensional (3D) scaling is advantageous.

Referring to FIG. 13, a microelectronic device structure 101 is formed to include a first semiconductor structure 110 including a semiconductor base 112 and semiconductor projections 113 (e.g., semiconductor pillars) vertically extending (e.g., in the Z-direction) from and integral (e.g., unitary) with the semiconductor base 112; and conductive line structures 121 (e.g., bit line structures, data line structures, digit line structures) on or over semiconductor projections 113. In some embodiments, the first semiconductor structure 110 is formed of and includes at least one semiconductive material, such as silicon (e.g., monocrystalline silicon, polycrystalline silicon). In addition, the microelectronic device structure 101 further includes trenches 122 vertically extending into the first semiconductor structure 110 in the Z-direction, horizontally extending in parallel in the X-direction, and horizontally interposed between neighboring semiconductor projections 113 and the neighboring conductive line structures 121 in the Y-direction. The trenches 122 are also referred to herein as x-axis trenches 122.

The x-axis trenches 122 may be formed to vertically terminate at a desirable vertical depth within the first semiconductor structure 110; such as, for example, a vertical depth within a range of from about 150 nm to about 300 nm (e.g., about 180 nm) from an uppermost surface of the first semiconductor structure 110. The semiconductor projections 113 may horizontally alternate in the Y-direction with x-axis trenches 122, and may individually have a height within a range of from about 150 nm to about 300 nm (e.g., about 180 nm). The semiconductor projections 113 may be formed to a width (e.g., to a width in a range of from about 10 nm to about 30 nm) in the Y-direction. The x-axis trenches 122 have horizontal boundaries partially defined by sidewalls 123 of neighboring semiconductor projections 113 and lower boundaries defined by upper surfaces 126 of the semiconductor base 112 of the first semiconductor structure 110.

With continued reference to FIG. 13, the first conductive line structures 121 are formed vertically on or over each of the semiconductor projections 113. The first conductive line structures 121 may be formed of and include a first conductive material 120. The first conductive material 120 may comprise one or more conductive materials. In some embodiments, the first conductive material 120 includes tungsten, either alone or in combination with one or more conductive barrier materials (e.g., oxidation-resistant materials which protect the tungsten from oxidation in embodiments in which the tungsten may be exposed to oxygen).

The first conductive line structures 121 may be formed to any suitable dimensions (e.g., width, thickness). By way of example, the first conductive line structures 121 may individually be formed to a width, in the Y-direction, equal to about the width of an individual semiconductor projections 113 (e.g., in a range of from about 10 nm to about 30 nm). The first conductive line structures 121 may be formed to any suitable pitch. The first conductive line structures 121 may be spaced apart from one another by a distance equal to about the distance between the semiconductor projections 113 horizontally neighboring one another in the Y-direction.

The first semiconductor structure 110 (including the semiconductor base 112 and the semiconductor projections 113), and the first conductive line structures 121 may be formed using any suitable processing. For instance, the first conductive material 120 may be formed on or over a semiconductor material; and then a material removal process (e.g., a process including photolithographic patterning and etching) may be effectuated to form the first conductive line structures 121, the first semiconductor structure 110 including the semiconductor base 112 and the semiconductor projections 113, and the x-axis trenches 122.

Referring next to FIG. 14, a first insulative material 130 is formed (e.g., non-conformally deposited) to fill the x-axis trenches 122 (FIG. 13) and to overlie the first conductive line structures 121 of the microelectronic device structure 101. A lower boundary of the first insulative material 130 may be non-planar, and an upper boundary of the first insulative material 130 may be substantially planar. In at least some embodiments, the first insulative material 130 comprises a dielectric oxide material, such as silicon dioxide.

The first insulative material 130 forms insulative structures 132 interposed between semiconductor projections 113 horizontally neighboring one another in the Y-direction. The semiconductor projections 113 and the insulative structures 132 may horizontally extend in parallel in the X-direction. In addition, the semiconductor projections 113 and the insulative structures 132 may horizontally alternate with one another in the Y-direction perpendicular to the X-direction.

In some embodiments, at least a portion of the first insulative material 130 is considered to be a dielectric bonding material. The first insulative material 130 may have an upper surface 131 that is substantially planar. The upper surface 131 may be formed using a suitable planarization process, such as CMP.

With continued reference to FIG. 14, the semiconductor projections 113 may be formed to individually include a first doped region 115 (e.g., a channel region) and a second doped region 117 (e.g., a drain region). One of the first doped region 115 and the second doped region 117 may be n-type doped while the other of the first doped region 115 and the second doped region 117 may be p-type doped. In some embodiments, the first doped region 115 is p-type doped, such as p-type doped to concentration in a range of from about −10¹³ cm⁻³ to about −10¹⁸ cm⁻³, and the second doped region 117 is n-type doped, such as n-type doped to concentration in a range of from about 10¹⁵ cm⁻³ to about 10²⁰ cm⁻³. In additional embodiments, the first doped region 115 is p-type doped to the point of saturation (e.g., greater than or equal to about −10¹⁸ cm⁻³). The doping of first doped region 115 and the second doped region 117 may be reversed so that the second doped region 117 is p-type doped and the first doped region 115 is n-type doped. In additional embodiments, the first doped region 115 does not include p-type dopant or n-type dopant (e.g., the first doped region 115 may, instead, be considered an undoped region). The second doped regions 117 may extend a distance downward from the upper boundaries of the semiconductor projections 113 (e.g., to a vertical depth within a range of from about 10 nm to about 50 nm from upper boundaries of semiconductor projections 113, such as from about 20 nm to about 30 nm). The doping may be accomplished utilizing any suitable processing, such as by implanting dopant (e.g., at least one n-type dopant or at least one p-type dopant) into the first semiconductor structure 110. Although the first doped regions 115 and the second doped regions 117 are first shown at the process stage of FIG. 14, the first doped regions 115 and the second doped regions 117 may be formed at an earlier process stage, such as the process stage previously described with reference to FIG. 13.

The semiconductor base 112, the semiconductor projections 113, the first conductive line structures 121, and the insulative structures 132 may be considered together to form a first assembly 133.

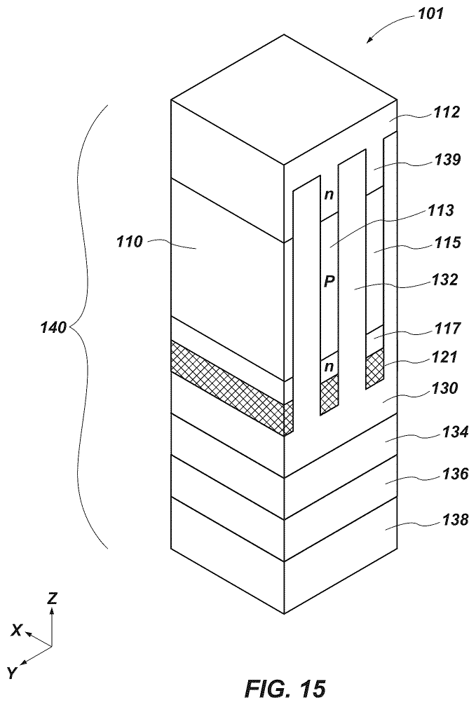

Referring to FIG. 15, the first assembly 133 of microelectronic device structure 101 may be inverted and attached (e.g., bonded) to a construction including a second semiconductor structure 134. In some embodiments, the first insulative material 130 is bonded to the second semiconductor structure 134. A material composition of the second semiconductor structure 134 may be substantially the same as or may be different than a material composition of the first semiconductor structure 110. In some embodiments, the second semiconductor structure 134 is formed of and includes at least one semiconductive nitride material, such as one or more of gallium nitride, aluminum nitride, and indium nitride.

As shown in FIG. 15, the second semiconductor structure 134 may be formed on or over a first dielectric material 136. In some embodiments, the first dielectric material 136 comprises insulative material, such as one or more of dielectric oxide material (e.g., silicon dioxide) and dielectric nitride material (e.g., silicon nitride). In addition, as also shown in FIG. 15, the first dielectric material 136 may be formed on or over a substrate 138. In some embodiments, the substrate 138 is formed of and includes semiconductive material (e.g., silicon). For example, the substrate 138 may comprise a semiconductive wafer, such as a silicon wafer. The combination of the first assembly 133 (FIG. 14), the second semiconductor structure 134, the first dielectric material 136, and the substrate 138 may form a second assembly 140.

Third doped regions 139 (e.g., source regions) may be formed in upper regions of the semiconductor projections 113. The third doped regions 139 may be n-type doped or may be p-type doped. In some embodiments, the third doped regions 139 are individually n-type doped, such as n-type doped to concentration in a range of from about 10¹⁵ cm⁻³ to about 10²⁰ cm⁻³. Doping may be accomplished utilizing suitable processing, such as implanting of appropriate dopant (e.g., n-type dopant, p-type dopant) into the upper regions of the semiconductor projections 113. Such processing may be effectuated prior to the formation of the first mask material 141. As shown, the third doped regions 139 extend downwardly from the upper ends of the semiconductor projections 113 (e.g., to a vertical depth within a range of from about 10 nm to about 50 nm from uppermost boundaries of the semiconductor projections 113, such as from about 20 nm to about 40 nm).

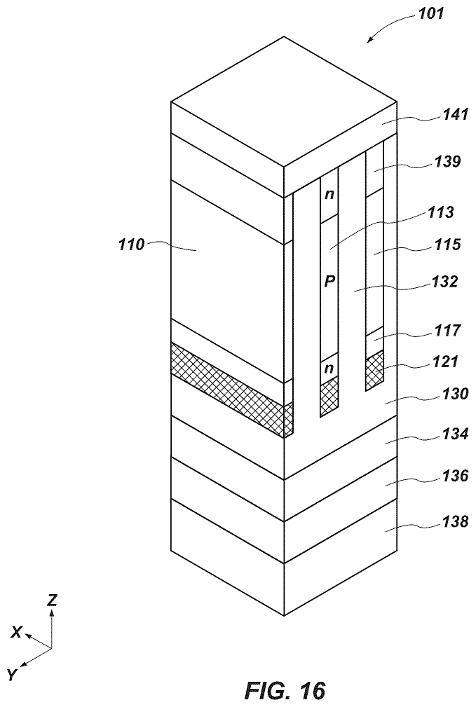

Referring to FIG. 16, a portion (e.g., at least the semiconductor base 112 (FIG. 15)) of the first semiconductor structure 110 is removed such that the upper ends of the semiconductor projections 113 are substantially coplanar with the upper ends of the insulative structures 132. In addition, a first mask material 141 may be formed over remainders of the semiconductor projections 113 and the insulative structures 132. In some embodiments, the first mask material 141 is formed of and includes dielectric material, such as dielectric nitride material (e.g., silicide nitride).

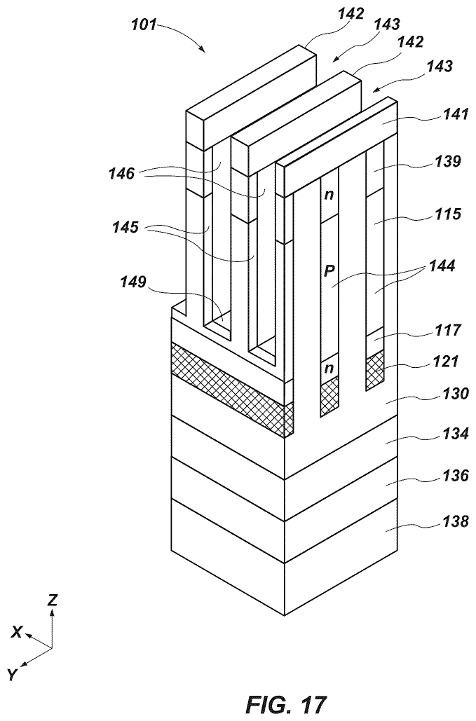

Referring to next FIG. 17, the first mask material 141 is patterned to form patterned masking lines 142 horizontally extending in parallel with one another in the Y-direction. The first mask material 141 may be patterned into the patterned masking lines 142 utilizing any suitable methodology. For instance, in some embodiments, a photoresist material is formed on or over the first mask material 141, is patterned (e.g., photoexposed and developed), and then openings formed in the patterned photoresist material are extended into the first mask material 141 to form the patterned masking lines 142. The patterned masking lines 142 may be removed during subsequent processing stages, or may remain in a final device formed through the methods of the disclosure.

The patterned masking lines 142 may be employed to form additional trenches 143 vertically extending into the first semiconductor structure 110 (FIG. 16) and the first insulative material 130 of the microelectronic device structure 101. The trenches 143 horizontally extend in parallel in the Y-direction, and are also referred to as y-axis trenches 143. The y-axis trenches 143 may have any suitable dimensions. In some embodiments, the y-axis trenches 143 have vertical depths (e.g., vertical heights) within a range of from about 100 nm to about 200 nm (e.g., about 150 nm).

The y-axis trenches 143 vertically extend in the Z-direction downward into and through portions of the semiconductor projections 113 (FIG. 16) and the insulative structures 132 (FIG. 16). The formation of the y-axis trenches 143 effectuates the formation of semiconductor pillars 144 from the semiconductor projections 113 (FIG. 16). The semiconductor pillars 144 have semiconductor pillar edges 145 (e.g., side surfaces) which are exposed by the y-axis trenches 143. Inner walls 146 of the first insulative material 130 (e.g., of remainders of the insulative structures 132 (FIG. 16)) are disposed between the semiconductor pillar edges 145 and are also exposed by the y-axis trenches 143.

In some embodiments, the y-axis trenches 143 are formed using an etching process (e.g., an anisotropic etching process) that selectively removes exposed portions of the first semiconductor structure 110 (FIG. 16) and the first insulative material 130 relative to the patterned masking lines 142. The exposed portions of the first semiconductor structure 110 and the first insulative material 130 may be removed at substantially the same rate as one another. Accordingly, lower boundaries (e.g., bottoms) of the y-axis trenches 143, as defined by upper surfaces 149 of the remainder of the first semiconductor structure 110 and the first insulative material 130, may be substantially planar.

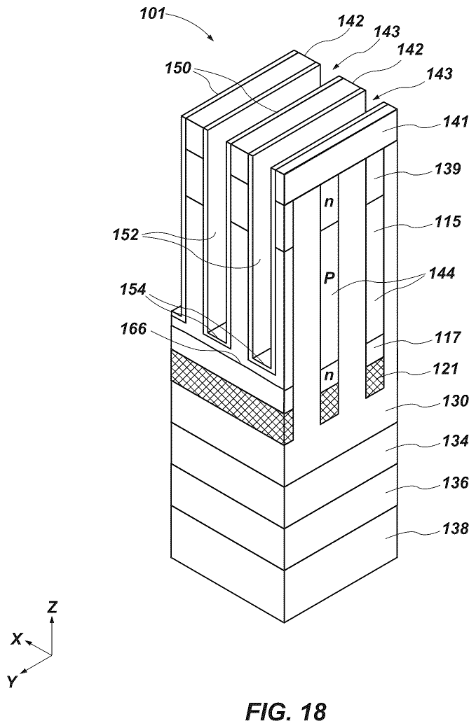

Referring to FIG. 18, dielectric liner material 150 is formed in the y-axis trenches 143 of the microelectronic device structure 101. The dielectric liner material 150 may also be referred to herein as a gate dielectric material 150. The gate dielectric material 150 is formed over and along the semiconductor pillar edges 145 (FIG. 17) of the semiconductor pillars 144 and the inner walls 146 (FIG. 17) of the first insulative material 130 disposed between the semiconductor pillars 144. Within the y-axis trenches 143, the gate dielectric material 150 may include side portions 152 on the semiconductor pillar edges 145 of the semiconductor pillars 144 and the inner walls 146 of the first insulative material 130, and, optionally, bottom portions 154 on or over the upper surfaces 149 (FIG. 17) of the remainder of the first semiconductor structure 110 (FIG. 16) and the first insulative material 130. Within an individual y-axis trench 143, the bottom portion 154 of the gate dielectric material 150 may be integral and continuous with the side portions 152 of the gate dielectric material 150. In some embodiments, the upper surfaces of the bottom portions 154 of the gate dielectric material 150 are vertically offset from (e.g., are vertically above) interfaces 166 between the first doped region 115 and second doped region 17 of the individual semiconductor pillars 144.

The gate dielectric material 150 may be formed of and include insulative material. In some embodiments, the gate dielectric material 150 is formed of and includes silicon dioxide. In some embodiments, the gate dielectric material 150 is formed (e.g., conformally deposited) inside and outside of the y-axis trenches 143, and then portions of the gate dielectric material 150 are removed (e.g., by way of CMP) while additional portions of the gate dielectric material 150 within the y-axis trenches 143 are maintained. The side portions 152 and the bottom portions 154 of the gate dielectric material 150 may have a thickness within a range of from about 3 nm to about 7 nm (e.g., about 5 nm).

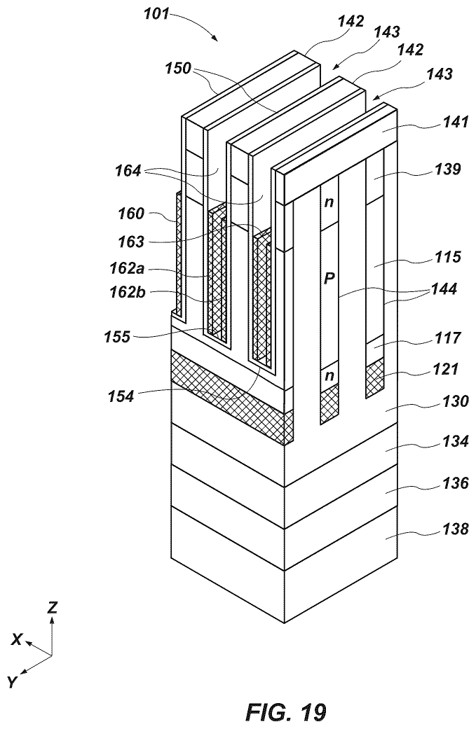

Referring to FIG. 19, a second conductive material 160 is formed within the y-axis trenches 143 and over the gate dielectric material 150. Within individual y-axis trenches 143, the second conductive material 160 may be horizontally interposed in the X-direction between the side portions 152 of the gate dielectric material 150, and may vertically overlie the bottom portion 154 of the gate dielectric material 150. In some embodiments, the second conductive material 160 is formed of and includes titanium nitride.

The second conductive material 160 may be formed (e.g., conformally deposited) along the side portions 152 and over the bottom portions 154 of the gate dielectric material 150 within the y-axis trenches 143, and then portions of second conductive material 160 are removed (e.g., by way of CMP) to form pairs of second conductive line structures 162a, 162b (e.g., gate electrodes, access lines, word lines) within the y-axis trenches 143. As shown in the illustrated embodiments, the second conductive line structures 162a, 162b are not interconnected (e.g., conductively interconnected, electrically interconnected) to one another with the second conductive material 160. In some embodiments, the bottom portions 154 of the gate dielectric material 150 may also be removed (e.g., by way of CMP). The second conductive line structures 162a, 162b may horizontally extend in parallel in the Y-direction. In some embodiments, the second conductive line structures 162a, 162b are employed as gate electrodes. The second conductive line structures 162a, 162b may vertically overlap the first doped regions 115 of the semiconductor pillars 144. In some embodiments, the second conductive line structures 162a, 162b are substantially confined within vertical boundaries of the first doped regions 115 of the semiconductor pillars 144. In additional embodiments, the second conductive line structures 162a, 162b also partially vertically overlap the second doped regions 117 of the semiconductor pillars 144.

Following the formation of the second conductive line structures 162a, 162b, remaining portions 164 of the y-axis trenches 143 may vertically overlie and extend between the second conductive line structures 162a, 162b. Upper surfaces 163 of the second conductive line structures 162a, 162b and the upper surfaces 155 of the bottom portions 154 of the gate dielectric material 150 may define bottoms of the remaining portions 164 of the y-axis trenches 143. In some embodiments, the upper surfaces 163 of the second conductive line structures 162a, 162b are vertically offset in the Z-direction from the upper surfaces of the patterned masking lines 142 by a distance within a range of from about 50 nm to about 150 nm, such as from about 75 nm to about 100 nm.

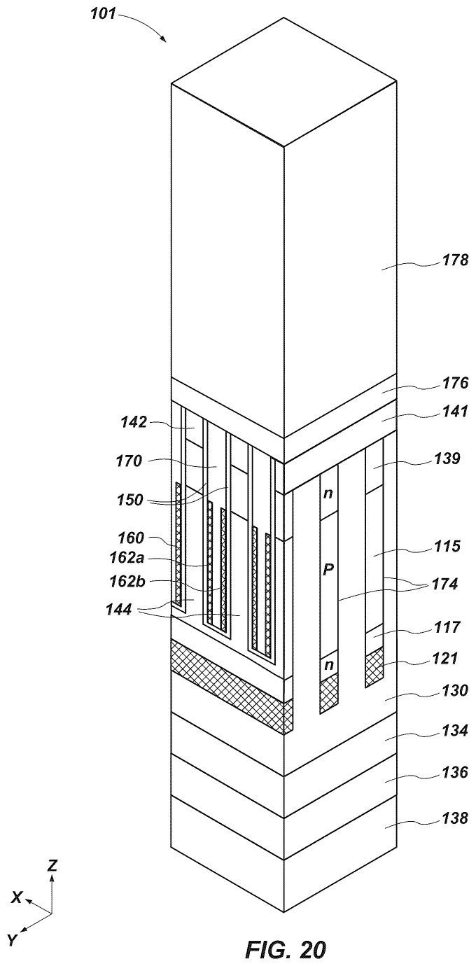

Referring to FIG. 20, a second insulative material 170 may be formed within and may substantially fill the remaining portions 164 (FIG. 19) of the y-axis trenches 143 (FIG. 19). The second insulative material 170 may be formed on or over the upper surfaces 163 of the second conductive line structures 162a, 162b, on or over the upper surfaces 155 (FIG. 19) of the bottom portions 154 (FIG. 19) of the gate dielectric material 150, and between the second conductive line structures 162a, 162b in the remaining portions 164 of the y-axis trenches 143. The second insulative material 170 may be formed to be substantially confined within the boundaries of the remaining portions 164 of the y-axis trenches 143 (e.g., using a CMP process following conformal deposition of the second insulative material 170). In some embodiments, the second insulative material 170 is formed of and includes dielectric oxide material (e.g., silicon oxide). In addition, after forming the second insulative material 170, a second mask material 176 may be formed over the patterned masking lines 142, the gate dielectric material 150, and the second insulative material 170, and a sacrificial mask material 178 may be formed over the second mask material 176. The second mask material 176 and the sacrificial mask material 178 may each have etch selectively relative at least to the second insulative material 170 and additional materials of storage node elements to be formed using the second mask material 176 (as described in further detail below). In some embodiments, the second mask material 176 is formed of and includes a dielectric nitride material (e.g., silicon nitride), and the sacrificial mask material 178 is formed of and includes an oxide material (e.g., silicon dioxide).

Still referring to FIG. 20, the semiconductor pillars 144 may form portions of vertical access devices 174 (e.g., vertical transistors). An individual vertical access device 174 may include a channel region comprising the first doped region 115 of an individual semiconductor pillar 144, a drain region comprising the second doped region 117 of the semiconductor pillar 144, and a source region comprising the third doped region 139 of the semiconductor pillar 144. In addition, the vertical access device 174 may include a gate electrode comprising one of the second conductive line structures 162a, 162b, and a gate dielectric material comprising the dielectric liner material 150. An individual second conductive line structure 162a, 162b may be utilized as a gate electrode for multiple vertical access devices 174.

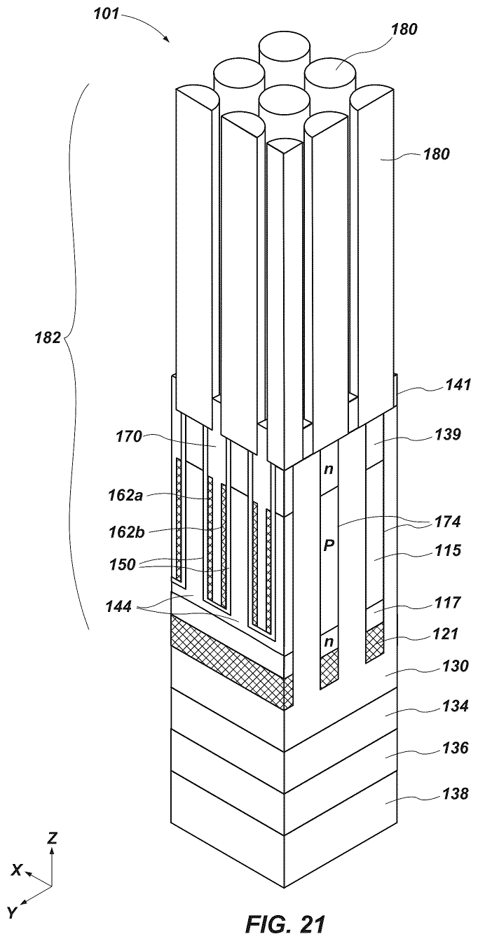

Referring to FIG. 21, openings may be formed to vertically extend through the sacrificial mask material 178 (FIG. 20), the second mask material 176 (FIG. 20) and the first mask material 141 of the patterned masking lines 142 (FIG. 20) and to at least partially expose the semiconductor pillars 144 (e.g., to the third doped regions 139 thereof). The openings may horizontally overlap and vertically extend to the semiconductor pillars 144. Storage node elements 180 (e.g., capacitors) are then formed within the resulting openings, and may be in electrical communication with the vertical access devices 174. The combination of an individual storage node element 180 and an individual vertical access device 174 forms a memory cell 182. As shown in FIG. 21, following the formation of the storage node elements 180, remaining portions of the sacrificial mask material 178 and the second mask material 176 may be substantially removed while maintaining the storage node elements 180. Remaining portions of the first mask material 141 may also be removed (e.g., substantially removed), or may be at least partially maintained, as shown in FIG. 21.

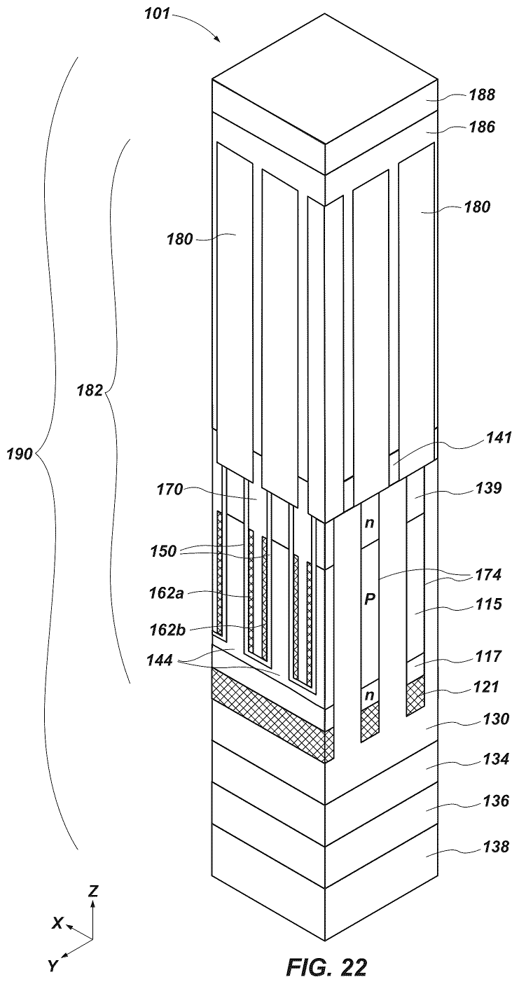

Referring to FIG. 22, following the removal of the remaining portions of the sacrificial mask material 178 (FIG. 20), the second mask material 176 (FIG. 20) (and, optionally, the first mask material 141), a third dielectric material 186 may be formed within the resulting void spaces between the storage node elements 180. As show in FIG. 22, the third dielectric material 186 may substantially cover and surround the storage node elements 180. Upper electrodes (not shown) of the storage node elements 180 may be operatively positioned (e.g., embedded) within the third dielectric material 186. A material composition of the third dielectric material 186 may be substantially the same as or may be different than that of the second insulative material 170. In some embodiments, the third dielectric material 186 is formed of and includes silicon oxide. In additional embodiments, the third dielectric material 186 is formed of and includes a high-k dielectric material, such as hafnium dioxide. A third insulative material 188 is formed (e.g., bonded) over the third dielectric material 186. In at least some embodiments, the third insulative material 188 comprises a dielectric oxide material, such as silicon dioxide. A third assembly 190 may result after the formation of the third dielectric material 186, as shown in FIG. 22.

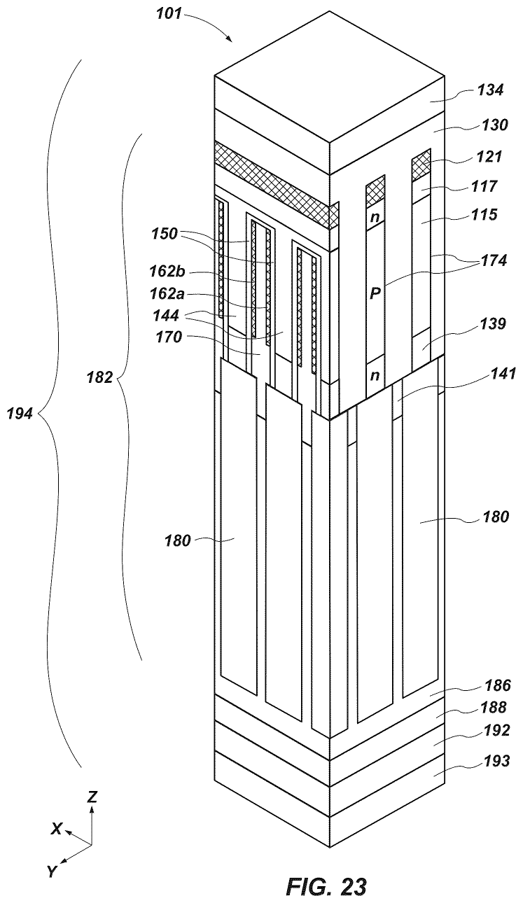

Referring to FIG. 23, additional substrates 192, 193 (e.g., additional wafers, such as additional silicon wafer) may be attached (e.g., bonded) to the third assembly 190 (FIG. 22), and then the resulting structure may be vertically inverted. In some embodiments, the additional substrates 192, 193 are attached to the third assembly 190 by way of a third insulative material 188 (e.g., dielectric oxide material). For example, a separate assembly including the additional substrates 192, 193 and the third insulative material 188 may be attached to the third assembly 190 by bonding the third insulative material 188 to the third dielectric material 186 of the third assembly 190. In addition, following inversion, the substrate 138 (FIG. 22) and the first dielectric material 136 (FIG. 22) may be removed while at least partially maintaining the second semiconductor structure 134. As shown in FIG. 23, a fourth assembly 194 may result from such process acts.

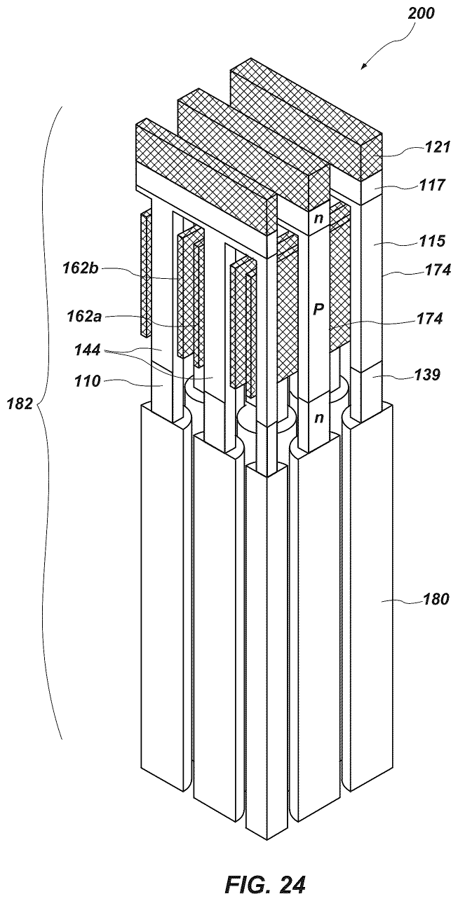

Referring to FIG. 24, a microelectronic device 200 formed through the process described with reference to FIGS. 13 through 23 is depicted. The microelectronic device 200 may have a 4F² cell architecture, and may include the fourth assembly 194 (FIG. 23). However, in FIG. 24 some features (e.g., material, structures) of the fourth assembly 194 are omitted for clarity and ease of understanding the drawing and related description. As shown in FIG. 24, the microelectronic device 200 may include an array of 4F² memory cells 182, wherein each memory cell 182 includes one of the vertical access devices 174 and one of the storage node elements 180 previously described herein.

An advantage of the processing of FIGS. 13-23 is that such may enable improved scalability of the vertical access devices 174 to higher levels of integration while reducing leakage between vertical access devices 174 than may be otherwise thereby possible thus permitting the formation of 4F² cell architectures.

FIGS. 13-24 may be considered to describe a second exemplary method of forming vertical transistors into 4F² cell architectures.

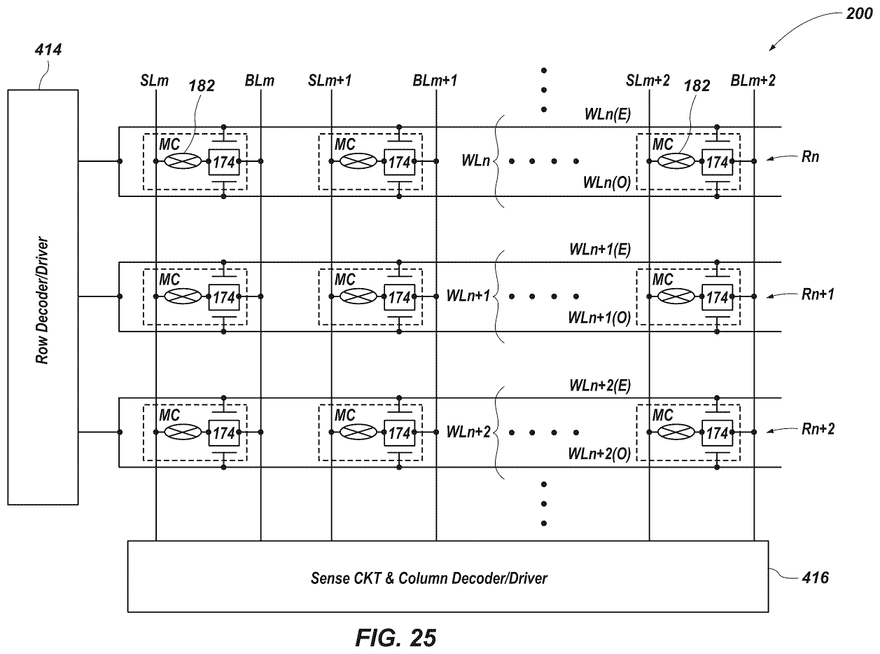

FIG. 25 shows a region of the microelectronic device 200 of FIG. 24 (e.g., a memory array) and regions of peripheral circuitries 414, 416 adjacent to the region of the microelectronic device 200. The microelectronic device 200 comprises a plurality of memory cells 182 (MC) and vertical access devices 174 (e.g., vertical transistors). Wordlines (WLₙ, WLₙ₊₁) are coupled with gates of the vertical access devices 174, and extend to wordline driver circuitry 414 (e.g., Row Decoder/Driver). In some embodiments, the wordlines may be considered to comprise a set of even wordlines (e.g., WLₙ (E)) and odd wordlines (e.g., WLₙ (O)), with the terms “even” and “odd” being utilized to enable one set of wordlines to be distinguished relative to another set, and are not to be understood as indicating any substantial structural difference between the wordlines. The even and odd wordlines alternate with one another across the microelectronic device 200.

Source lines (e.g., SLₘ, SLₘ₊₁) are coupled with the memory cells 182, and bitlines (e.g., BLₘ, BLₘ₊₁) are coupled with the vertical access devices 174. The source lines and bitlines extend to sense circuitry, column decoder circuitry, and column driver circuitry 416 (e.g., Sense CKT & Column Decoder/Driver). Thus, each of the memory cells 182 is uniquely addressed through a combination comprising one of the source lines, one of the bitlines, and one of the wordlines.

The vertical access devices 174 are arranged in rows (e.g., Rₙ, Rₙ₊₁) across the microelectronic device 200, with each row disposed between an even wordline (e.g., WLₙ (E)) and an odd wordline (e.g., WLₙ (O)). The vertical access devices 174 comprise the semiconductor pillars 144 (FIG. 24), and accordingly the semiconductor pillars 144 are also arranged in the same rows as the vertical access devices 174.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternate useful combinations of the elements described, will become apparent to those skilled in the art from the description. Such modifications and embodiments also fall within the scope of the appended claims and equivalents.

What is claimed is:

1. A microelectronic device, comprising:
a vertical access device, comprising:
a semiconductor pillar comprising:
a first portion having a first width in a first horizontal direction and comprising:
a source/drain region; and
a portion of a channel region vertically adjacent the source/drain region; and
a second portion vertically adjacent the first portion and having a second width in the first horizontal direction larger than the first width, the second portion comprising:
an additional portion of the channel region; and
an additional source/drain region vertically adjacent the additional portion of the channel region; and
a gate electrode neighboring a sidewall of the semiconductor pillar in a second horizontal direction orthogonal to the first horizontal direction, the gate electrode vertically overlapping each of the first portion and the second portion of the semiconductor pillar.

2. The microelectronic device of claim 1, wherein the semiconductor pillar further comprises a pair of ledges at an intersection of the first portion and the second portion thereof, each of the ledges having a third width in the first horizontal direction and the sum of the third widths substantially equal to the difference between the first width and the second width.

3. The microelectronic device of claim 2, wherein the gate electrode vertically overlaps the ledge of the semiconductor pillar.

4. The microelectronic device of claim 1, wherein a magnitude of the first width of the first portion of the semiconductor pillar is within a range of from about 15 percent to about 60 percent of a magnitude of the second width of the second portion of the semiconductor pillar.

5. The microelectronic device of claim 1, wherein a vertical height of the portion of a channel region is smaller than a vertical height of the additional portion of a channel region.

6. The microelectronic device of claim 1, wherein the gate electrode is completely vertically offset from each of the source/drain region and the additional source/drain region.

7. The microelectronic device of claim 1, wherein the first portion and the second portion of the semiconductor pillar have substantially the same length as one another in the second horizontal direction.

8. The microelectronic device of claim 1, further comprising a gate dielectric material horizontally between the gate electrode and the sidewall of the semiconductor pillar in the second horizontal direction, the gate dielectric material substantially covering at least one sidewall of the gate electrode and one of a top surface and a bottom surface of the gate electrode.

9. The microelectronic device of claim 1, wherein:
the source/drain region and the additional source/drain region each have N-type conductivity; and
the channel region has P-type conductivity.

10. The microelectronic device of claim 1, wherein the channel region comprises semiconductor material substantially saturated with one or more conductivity-enhancing dopants.

11. The microelectronic device of claim 1, further comprising:
a conductive line structure vertically neighboring and coupled to the source/drain region of the vertical access device; and
a storage node device vertically neighboring and coupled to the additional source/drain region of the vertical access device.

12. A method of forming a microelectronic device, comprising:
forming a preliminary structure comprising:
semiconductive projections vertically extending from a semiconductive base and horizontally extending in a first direction, the semiconductive projections each including:
a first portion having a first horizontal width in a second direction orthogonal to the first direction; and
a second portion having a second horizontal width in the second direction, the second horizontal width smaller than the first horizontal width;
conductive line structures on the semiconductive projections; and
dielectric material horizontally interposed between the semiconductive projections and the conductive line structures in the second direction;
forming trenches vertically extending through the semiconductive projections and the dielectric material and respectively horizontally extending in the first direction, the trenches forming semiconductor pillars from the semiconductive projections;
partially filling the trenches with gate dielectric material;
forming gate electrodes within the trenches and on the gate dielectric material; and
filling remaining portions of the trenches with additional dielectric material after forming the gate electrodes.

13. The method of claim 12, wherein forming trenches vertically extending through the semiconductive projections and the dielectric-filled trenches comprises:
vertically inverting the preliminary structure;
forming a patterned mask over the preliminary structure after inverting the preliminary structure, the patterned mask more proximate to the first portion of each of the semiconductive projections than the second portion of each of the semiconductive projections; and
forming the trenches after forming the patterned mask, the trenches respectively vertically terminating at or above the conductive line structures.

14. The method of claim 13, further comprising doping the semiconductive projections with one or more conductivity-enhancing dopants after inverting the preliminary structure and before forming the patterned mask over the preliminary structure.

15. The method of claim 13, wherein partially filling the trenches with gate dielectric material comprises substantially conformally depositing the gate dielectric material at least on exposed surfaces of the patterned mask, the semiconductor pillars, and remaining portions of the dielectric material.

16. The method of claim 15, wherein forming gate electrodes within the trenches comprises:
substantially filling portions of the trenches remaining unfilled with the gate dielectric material with conductive material; and
removing upper portions of the conductive material to form the gate electrodes, upper boundaries of the gate electrode below upper boundaries of the semiconductor pillars.

17. The method of claim 12, wherein further comprising forming storage node structures over the semiconductor pillars after filling remaining portions of the trenches with additional dielectric material.

18. The method of claim 12, wherein forming storage node structures on the semiconductor pillars comprises forming capacitors over and in electrical communication with the semiconductor pillars.

19. A memory device, comprising:
memory devices each comprising:
a vertical access device, comprising:
a semiconductor pillar comprising:
a first portion having a first width in a first horizontal direction and comprising:
a source/drain region; and
a portion of a channel region vertically adjacent the source/drain region; and
a second portion vertically adjacent the first portion and having a second width in the first horizontal direction larger than the first width, the second portion comprising:
an additional portion of the channel region; and
an additional source/drain region vertically adjacent the additional portion of the channel region; and
a gate electrode neighboring a sidewall of the semiconductor pillar in a second horizontal direction orthogonal to the first horizontal direction, the gate electrode partially vertically overlapping each of the first portion and the second portion of the semiconductor pillar; and
a storage node device vertically neighboring and in electrical communication with the additional source/drain region of the vertical access device; and
conductive line structures vertically neighboring and in electrical communication with the memory devices, the conductive line structures relatively more vertically proximate to the vertical access device of each of the memory devices than the storage node device of each of the memory devices.

20. The memory device of claim 19, wherein the memory devices comprise one of dynamic random access memory (DRAM) devices, high-resistive random access memory (HRAM) devices, ferroelectric random access memory (FeRAM) devices, synchronous dynamic random access memory (SDRAM) devices, resistive random access memory (RRAM) devices, conductive bridge random access memory (conductive bridge RAM) devices, magnetic random access memory (MRAM) devices, phase change random access memory (PCRAM) devices, and spin-torque-transfer random access memory (STTRAM) devices.
